(19) United States
(12) Patent Application Publication
(10) Pub. No.: US 2009/0245541 A1
(43) Pub. Date: Oct. 1, 2009

(54) Audio Power Amplifier with Feedback-Shifting Technology

(76) Inventor: Zhenwu Wang, Thousand Oaks, CA (US)

Correspondence Address: ZHENWU WANG, 555 LAURIE LANE, APT F5, THOUSAND OAKS, CA, 91360, US

(21) Appl. No.: 12/467,272

(22) Filed: May 16, 2009

Related U.S. Application Data
(60) Provisional application No. 61/210,227, filed on Mar. 16, 2009.

(51) Int. Cl. H03F 99/00

(52) U.S. Cl. 381/121

(57) ABSTRACT

A solid stage audio power amplifier comprises of two output stages with one generating the real output signal that drives the real loud speaker load and the other mimicking the real output stage and generating a dummy output signal that drives a dummy resistor load. A frequency dependent feedback selection network, denoted as Feedback-Shifting network hereafter, is implemented between the two outputs and the input of the amplifier to fulfill a unique global feedback loop. In a particular embodiment, the Feedback-Shifting network can be constructed so that it receives more feedback information from the real output node than from the dummy output node at low frequencies, but less feedback information from the real output node than from the dummy output node at mid to high frequency bands. Such a power amplifier performs as a traditional solid state feedback amplifier at low frequencies by generating a clear and tight bass, but it sounds similar to an open loop tube amplifier at higher frequencies by reproducing natural mid-band and treble with less listening fatigue.

### CROSS REFERENCE OF RELATED APPLICATION

This is a regular application of a provisional application having an application number of 61/210,227 and a filing date of Mar. 16, 2009.

### BACKGROUND OF THE INVENTION

The invention relates to solid state audio power amplifiers for driving loud speaker systems to carry out high quality sound reproduction.

Solid state audio power amplifiers usually adopt overall negative feedback loops in order to reduce distortions and improve other key characteristics as shown in FIG. 1. However, since the speaker system which the amplifier drives is not a simple resistive load, the moving voice coil also generates back Electro Motive Force (EMF) and feeds it back to the input of the amplifier through the global feedback loop. This back EMF signal inevitably interferes with the incoming input signal, causing unwanted effect in the reproduced sound like missing the subtle detail of music, constraining the soundstage and causing listening fatigue as claimed by many audiophiles. Therefore non-feedback design is preferred and getting popularity among audio power amplifier products.

However, non-feedback audio power amplifier has two big problems need to be solved: non-linear distortions, especially the crossover distortion generated by the output stage, and the high output impedance. The crossover distortion generates numerous odd number high order harmonics which will cause listening fatigue and greatly degrade the perceived sound quality. The high output impedance simply means low damping factor, a loud speaker driven by an amplifier with low dumping factor will easily resonate at the low frequency band, causing a wobbly bass reproduction. The traditional solution is to utilize excessively multiple output power devices working in parallel and operated at class A bias. Such a solution inevitably increases the cost and power consumption, making the technique only suitable in the very limited high-end market.

A unique approach presented by Charles Altmann in his patent [DE10034987 (A1)] tries to solve the distortion and output impedance problem through a feedback splitting technology as shown in FIG. 2. A replica of the output stage is added in parallel to the real output stage with a dummy resistive load connected; an overall feedback is also configured through the dummy output. The dummy resistive load is used to resemble the resistive component of the real speaker load, i.e., to have its resistance equal to the nominal impedance of the loud speaker, if the dummy output stage is a 1:1 duplicate of the real output stage. In practical applications, the dummy output stage is usually down-scaled to mitigate the cost and power consumption increase, thus the dummy resistor should also be down-scaled, i.e., have its resistance value increased inversely proportional to the same down-scale ratio to assure the resemblance between the load included real output stage and the dummy output stage. Since the dummy output stage is within a feedback loop, superior distortion performance and low output impedance can be achieved on the output of the dummy output stage. As long as the load included dummy output stage maintains its electrical similarity to the load included real output stage, the real output signal will track the dummy output signal closely, making the amplifier's distortion and output impedance performance similar to a traditional feedback amplifier. This method greatly reduced the cost and the power consumption because the output stage no longer needs to work under class A biasing in order to achieve a decent performance.

However, this idea also has a problem. While an amplifier employing such a technology generates very natural and delicate sound in the mid and high frequency band and establishes a lifelike soundstage, it's bass reproduction is perceived to be slow and wooly, missing the tightness and the clarity available from a traditional solid state amplifier with overall feedback implemented.

The reason for the dissatisfying bass reproduction is the impedance mismatch between the real speaker system and the dummy resistive load in the low frequency end. Most loud speaker systems exhibit impedance peak at the 50 Hz to 100 Hz frequency range due to the resonance nature of the mechanical system consisted by the mass, the suspension and the enclosure of the woofer. Such a peak impedance can be 3 to 5 times higher than the speaker's nominal impedance, greatly diminishes the resemblance between the real output stage and the dummy output stage around the resonance frequency, making the effort to improve the distortion and output impedance performance much less effective.

The shortcoming of the solution mentioned above strongly restricts its application in real amplifier products. An amplifier utilizing the technology only suits for playing of limited music categories like chamber and string music, but clearly doesn't suit for most other music classes like pop and Rock & Roll. In order to fully reach the goal of the low cost high performance amplifier design, a more effective and versatile method is required.

### SUMMARY OF THE INVENTION

The present invention is accomplished upon the previously mentioned circumstances. An object of the invention is to provide a low cost high performance amplifier which overcomes the drawback of the referred feedback split technology as previously discussed.

In order to attain the above object, a feedback shifting network is further added to the feedback split technology to solve the distortion and output impedance problem at the frequency low end. An audio power amplifier in accordance with a particular embodiment of the invention comprises:
an input stage which receives input signal and feedback signal and performs signal amplification;
a voltage amplification and buffer stage which follows the input stage, receives the output signal of the input stage and performs further signal amplification;
a real output stage which receives the output signal of the voltage amplification and buffer stage, generates the real output signal and drives a loud speaker load;
a dummy output stage which receives the same output signal of the voltage amplification and buffer stage, generates a dummy output signal and drives a dummy resistive load;
a frequency dependent feedback selection network which has two feedback paths, with one of which being connected to the real output node and the other one being connected to the dummy output node;
a global feedback network which combines the two feedback signals together and transfers it back to the input of the amplifier.
wherein the dummy output stage is either a 1:1 or a down-scaled replica of the real output stage, while the dummy resistor has its value either equal to the nominal impedance value of the loud speaker, or equal to the speaker's nominal impedance value multiplied by the reciprocal of the above motioned down-scale ratio, respectively.

In accordance with another embodiment of the invention, an audio power amplifier as described above is further characterized: the feedback path which is connected to the real output node is resistive or inductive while the other feedback path which is connected to the dummy output node is capacitive.

### BRIEF DESCRIPTION OF THE DRAWING

FIG. 1 is a block diagram illustrating the configuration of conventional power amplifier configuration

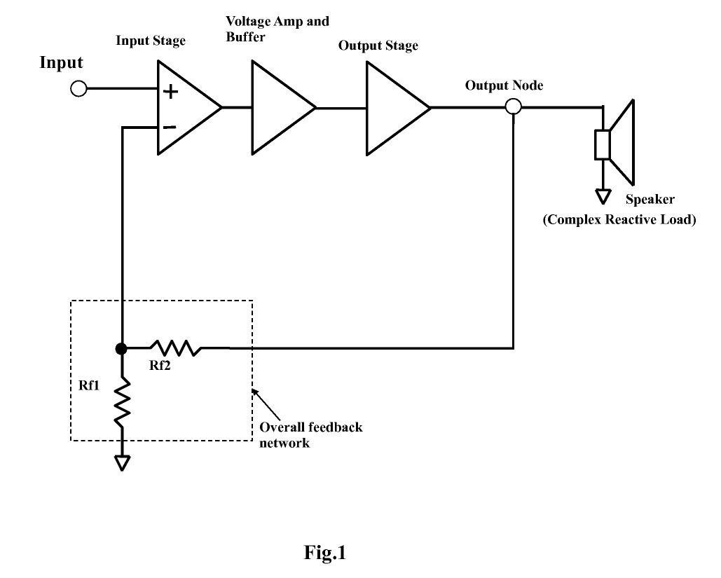

FIG. 2 is a block diagram illustrating the existing Feedback Splitting Technology

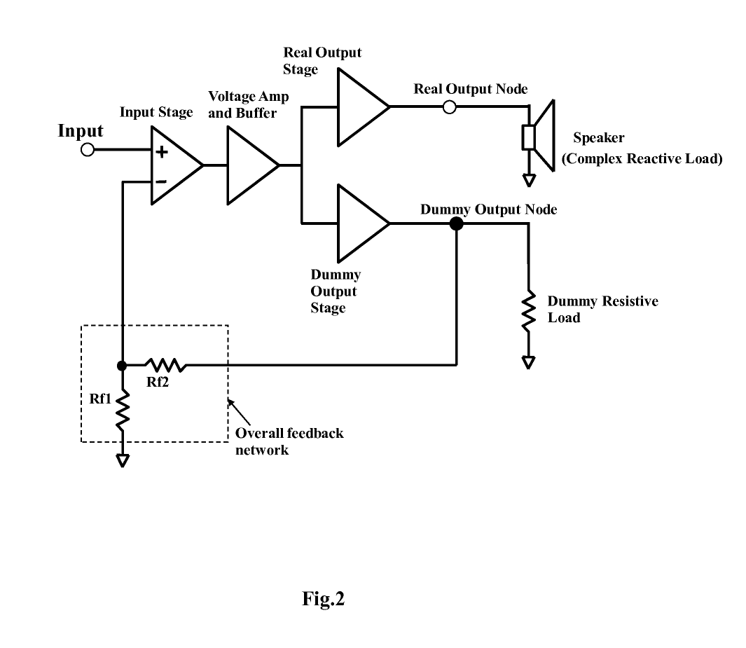

FIG. 3 is a block diagram illustrating an amplifier with the new Feedback-Shifting Technology

FIG. 4 is a schematic diagram illustrating a sample power amplifier utilizing the new technology

FIG. 5 is a schematic diagram illustrating the variations of the Feedback-Shifting network

### DESCRIPTION OF THE PREFERRED EMBODIMENTS

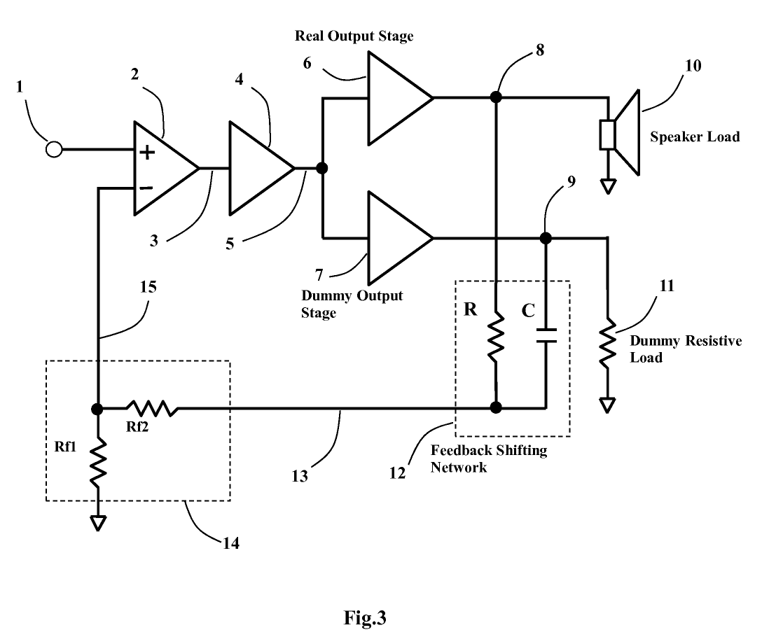

FIG. 3 shows an audio power amplifier block diagram according to one embodiment of the invention. The amplifier comprises an input node 1, an input stage 2, a voltage amp and buffer 4, a real output stage 6, a dummy output stage 7, a speaker load 10 which is connected to the output node 8 of the real output stage 6, a dummy resistive load 11 which is connected to the output node 9 of the dummy output stage 7, a Feedback-Shifting network 12, a global feedback network 14 which consists of resister Rf1 and Rf2 and is connected between the center point 13 of the feedback shifting network 12 and the inverting input node 15 of the input stage 2.

The input signal is amplified by the input stage 2 and passed to the voltage amp and buffer 4 through its output node 3. The amplified signal is further amplified and passed to the input of the real output stage 6 and the input of the dummy output stage 7 through the output node 5 of the voltage amp and buffer 4. The two output stages are unity gain buffers and both comprise the same circuit configurations and exhibit the same electric characteristics. The dummy output stage 7 could be either identical to the real output stage 6, or a down scaled copy of the real output stage 6. The phrase ‘down scaled’ here means size reduction, for example, when multiple identical power devices are used in parallel to increase the output power, which is almost always the case of amplifier design, the dummy output stage 7 can use a single pair of power transistors instead of multiple ones to reduce cost and power consumption. In order to achieve a resemblance between the dummy output signal and the real output signal, the dummy resistive load 11 should also match the speaker load 10, i.e., the resistance of the dummy output resistive load 11 should be equal to the nominal impedance value of the speaker load 10 if the dummy output stage 7 is an identical copy of the real output stage 6, or it should be equal to the speaker's nominal impedance value multiplied by the reciprocal of the same down scale value if the dummy output stage is down scaled. The Feedback-Shifting network 12 has two paths, one path of which is connected to the real output node 8 and the other path is connected to the dummy output node 9. The two paths of the Feedback-Shifting network 12 are connected together at the center point 13 of the network. The two paths is designed to have different frequency characteristics and carry out a frequency dependent feedback shifting mechanism: in general, at a certain frequency band one feedback path shows smaller impedance than the other so that the combined overall feedback signal which is fed back through the global feedback network 14 to the inverting input of the input stage 2 is dominated by the first mentioned feedback path, while at the other frequencies the other feedback path shows smaller impedance than the first mentioned path so that the overall feedback is dominated by the second mentioned feedback path. This arrangement effectively enables the amplifier to work at a selected frequency band similar to an amplifier utilizing global feedback when the feedback signal is mainly taken from the real output node 8, while at the other frequencies behave like a non feedback amplifier when the feedback signal is mostly taken from the dummy output node 9. In the specific embodiment of the invention as shown in FIG. 3, the feedback shifting network 12 consists of a resistor R and a capacitor C, with the resistor R connected between the real output node 8 and the center point 13 of the network and the capacitor C connected between the dummy output node 9 and the same center point 13 of the network. Such a RC network establishes a resistive path between the real output node 8 and the center point 12 and a capacitive path between the dummy output node 9 and the center point 12. At frequencies higher than the frequency point determined by the RC constant of the RC network, the feedback signal is mainly taken from the dummy output node 9, the amplifier behaves close to a non feedback amplifier, with its output signal tracking the dummy output signal, similar to the feedback splitting technology described before; while at the frequencies lower than the frequency point associated with the RC constant, the feedback signal is essentially taken from the real output node 8, which makes the amplifier behave more like a traditional closed loop feedback amplifier, greatly reducing the distortion and the output impedance at the low frequency band as desired.

The new approach retains both the advantage of the feedback split technology and the strength of the traditional feedback design at the same time, effectively solved the feedback vs non-feedback dilemma.

The frequency turning point of the RC network as shown in FIG. 3 can be set somewhere between 100 Hz to 500 Hz. The value of the resister R can be chosen between several ohm to several hundred ohm, and the capacitance of the capacitor C can be derived accordingly.

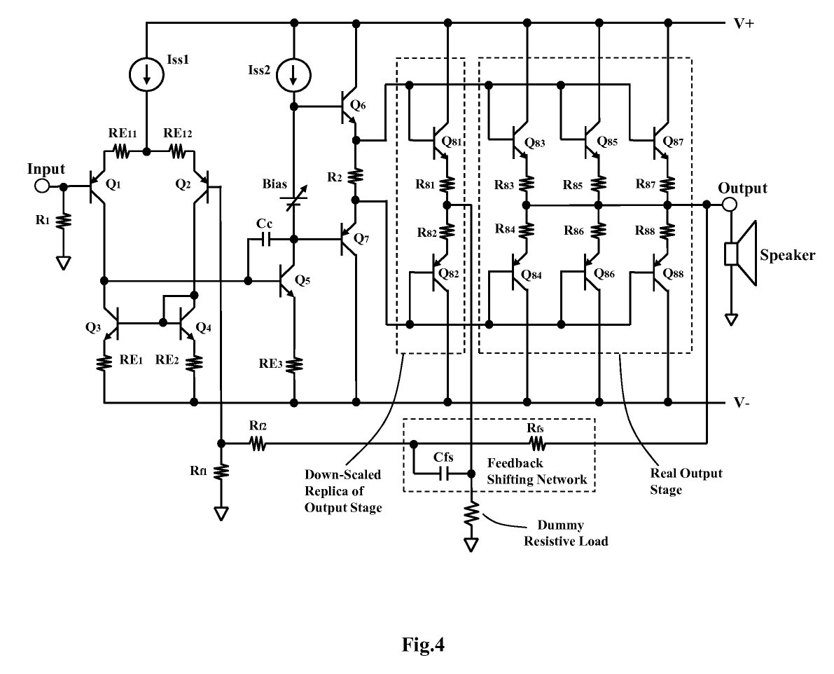

A practical power amplifier which utilizes the present invention is shown in FIG. 4. In addition to the traditional input and the second stages, the amplifier comprises of a real output stage, a dummy output stage, a feedback shifting RC network and a global feedback network. The input stage is a differential trans-conductance amplifier which has two voltage input nodes and one current output node, consisting of a input resister R1, a common-emitter transistor pair Q1/Q2, a local feedback resister pair RE11/RE12, a current source Iss1, a current mirror transistor pair Q3/Q4 and their emitter resister pair RE1/RE2. The second stage is a voltage amplifier and buffer which further amplifies the input current signal coming from the first stage and transfers it to an amplified voltage signal through a voltage follower, the voltage amplifier is a common-emitter configured single transistor trans-impedance amplifier which comprises of a transistor Q5, a biasing resister RE3, a Miller compensation capacitor Cc and a current source Iss2; the voltage buffer is a emitter follower pair which consists of an emitter follower transistor pair Q6/Q7 and a biasing voltage generator Bias. The real output stage is a voltage-follower which provides current amplification to gain enough power to drive the loud speaker load, consisting of three power emitter-follower transistor pairs in parallel: Q83/Q84, Q85/Q86 and Q87/Q88, and their associated emitter resister pairs: R83/R84, R85/R86 and R87/R88. The dummy output stage is a 3:1 down sized copy of the real output stage, comprising only one emitter-follower transistor pair Q81/Q82 and one emitter resister pair R81/R82. The dummy load resister should therefore has its resistance value equal to 3 times as big as the nominal impedance value of the loud speaker so the dummy output signal will closely track the real output signal with the maximum accuracy. The feedback shifting network is a RC network as described before and comprises a resister Rfs and a capacitor Cfs. The global feedback network is a voltage dividing resister network and comprises of resisters Rf1 and Rf2.

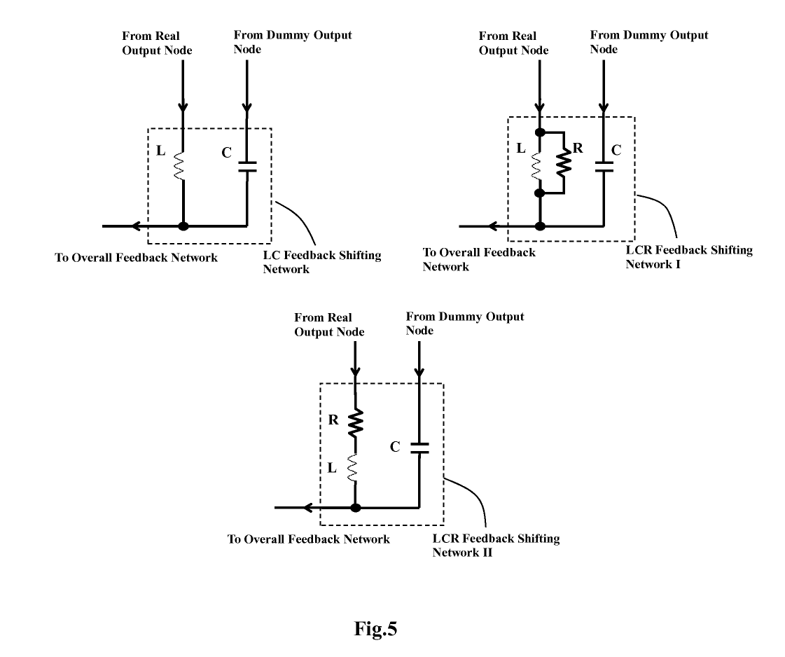

The feedback shifting network can have other circuit configurations, as shown in FIG. 5. The parameters of each network can be determined as follows: for the LC feedback shifting network, set the LC resonant frequency to be somewhere between 100 Hz to 500 Hz, and then set the impedance of the inductor L or the impedance of the capacitor C at the resonant frequency to be a value between several ohm to several hundred ohm. For the LCR feedback shifting network I and II, the inductance value of the inductor L and the capacitance value of the capacitor C can be determined the same way as described above for the LC feedback shifting network; the resistance value of the resistor R in the LCR feedback shifting network I can be chosen from several tens of ohm to several kilo ohm; the resistance value of the resistor R in the LCR feedback shifting network II can be set from several ohm to several hundred ohm.

It should be noted that the practice of the present invention is not limited to the embodiments as disclosed herein. Any variations and modifications established upon the spirit of the revealed technology which are apparent to those skilled in the field should also be considered a specific embodiment of the invention.

The present invention provides a low cost high performance audio power amplifier design technique over conventional feedback/non feedback amplifier designs. A unique feedback shifting technology is revealed to achieve both the benefits of the non feedback and feedback designs.

What is claimed is:

1. An audio power amplifier comprising:
an input stage which receives input signal and feedback signal and performs signal amplification;
a voltage amplification and buffer stage which follows said input stage, receives the output signal of said input stage and performs further signal amplification; two output stages, wherein one output stage has a real output node and generates real output signal to drive a loud speaker load, wherein the other output stage has a dummy output node and generates dummy output signal to drive a dummy resistive load, wherein both said output stages are unity gain amplifiers and receive the same output signal from said voltage amplification and buffer stage as their inputs;
a frequency dependent feedback shifting network which has two feedback paths, wherein one path has its one end connected to said real output node, the other path has its one end connected to said dummy output node, and said two paths are connected together at the remaining two ends and are further connected to a global feedback network;
a global feedback network, as recited above, is a resistor network and consists of two serially connected resistors, wherein one end of said resistor network is connected to said connection point of said two feedback paths, the other end of said resistor network is connected to system ground, and the connection point of said two resistors is connected to said input stage to form a global feedback.

2. An audio power amplifier, as recited in claims 1, wherein said dummy output stage is a down-scaled replica of said real output stage, and said dummy resistive load is a resistor with its resistance value equal to said loud speaker's nominal impedance value increased inversely proportional to said down-scale ratio determined by said dummy output stage versus said real output stage.

3. An audio power amplifier, as recited in claims 1, wherein said feedback path which is connected to said real output node exhibits resistive or inductive characteristic, i.e., shows constant or accumulative impedance with frequency increasing, while said feedback path which is connected to said dummy output node exhibits capacitive characteristic, i.e., shows declining impedance with frequency increasing.

4. An audio power amplifier, as recited in claims 3, wherein said resistive or inductive feedback path is a resistor and said capacitive feedback path is a capacitor.

5. An audio power amplifier, as recited in claims 3, wherein said resistive or inductive feedback path is an inductor and said capacitive feedback path is a capacitor.

6. An audio power amplifier, as recited in claims 3, wherein said resistive or inductive feedback path consists of an inductor and a resistor, wherein said inductor and resistor are connected in parallel, and said capacitive feedback path is a capacitor.

7. An audio power amplifier, as recited in claims 3, wherein said resistive or inductive path consists of an inductor and a resistor, wherein said inductor and resistor are connected in serial, and said capacitive feedback path is a capacitor.
